(19) United States
(12) Patent Application Publication
(10) Pub. No.: US 2002/0158646 A1
(43) Pub. Date: Oct. 31, 2002

(54) Spiral leaf spring contacts

(75) Inventor: Louis DiFrancesco, Hayward, CA (US)

Correspondence Address: DORSEY & WHITNEY, LLP, INTELLECTUAL PROPERTY DEPARTMENT, 370 SEVENTEENTH STREET, SUITE 4700, DENVER, CO, 80202-5647, US

(73) Assignee: NanoPierce Technologies, Inc., Denver, CO

(21) Appl. No.: 10/177,035

(22) Filed: Jun. 20, 2002

Related U.S. Application Data
(63) Continuation of application No. 08/843,019, filed on Apr. 11, 1997, now abandoned.
Application No. 08/843,019 is a continuation of application No. 08/855,964, filed on May 14, 1997, now abandoned.
Application No. 08/855,964 is a division of application No. 08/440,497, filed on May 10, 1995, now abandoned.

(51) Int. Cl. G01R 31/02

(52) U.S. Cl. 324/761; 324/754

(57) ABSTRACT

A contact comprising an electrically conductive material plate defining a central planar contact base. A plurality of integral contact leaves extend spirally from the base, and a plurality of integral mounting tabs extend radially from the base. The leaves are mechanically deformed from the plane of the base to form independent spring contacts. The tabs are coplanar with the base. A metal plating containing interconnect particles is provided on the contact base and leaves.

### CROSS REFERENCE TO RELATED APPLICATIONS

This application claims priority to each of the following applications: this application is a continuation of application no. 09/843,019 filed April 25, 2001; which is a continuation of application no. 08/855,964 filed May 14, 1997, now abandoned; which is a division of application no. 08/440,497 filed May 10, 1995, now abandoned; each of which is incorporated by reference as though fully set forth herein.. This application is further related to U.S. Pat. No. 5,471,151, which is also incorporate by reference as though fully set forth herein.

### BACKGROUND OF THE INVENTION

1. Field of the Invention

The invention relates to the handling of electronic devices. More particularly, the invention relates to contacts for connecting electronic devices, parts, and equipment.

2. Description of the Related Art

Electronic devices must be manipulated for various reasons during their fabrication, assembly, and testing. In fact, device handling is becoming one of the most critical steps in the manufacture of electronic devices because excessive handling can damage the devices, for example, by breaking or bending package leads, and because the physical handling of such parts, typically on an individual basis, takes considerable time, thereby limiting throughput. Further, the specific equipment designed for handling fine leads requires highly trained employees, and thus increases the costs of the manufacturing process.

In the prior art, various means were used to join the components of electrical devices. Deak et al, Flexible Area Array Connector, U.S. Pat. No. 5,007,842 (Apr. 16, 1991) used a forced application plate to hold a canted coiled spring in place, thereby urging stacked substrates into electrical contact. Coiled springs are flexible and are subject to mechanical deformation. Thus, this apparatus does not readily permit the rigid joining of substrates in fixed, precisely-spaced or variably-spaced alignment. Casciotti et al, Canted Coil Spring Interposing Connector, U.S. Pat. No. 5,061,191 (Oct. 29, 1991) electrically connects stacked, mechanically fastened components with conductive coiled springs, and is thus similarly subject to the problem of mechanical deformation.

In Grabbe, Area Array Connector, U.S. Pat. No. 5,173,055 (Dec. 22, 1992), cantilevered contact fingers provide the electrical contact between components. The circuit boards of Grabbe define apertures known as vias. In the prior art, a via is lined with a plating of conductive material. This plating process requires dipping the board into approximately 23 tanks, many of which contain extremely toxic materials requiring extra ventilation of the manufacturing facility as well as compliance with Environmental Protection Agency regulations. The plated material projects from the board to form an annulus surrounding the via aperture. Lack of precision in the lining process requires the drilling of an enlarged via. Electrical contact is maintained by bringing a cantilevered contact finger and annulus into aligned contract, and their imperfect alignment results in signal propagation delay. This process is costly and time-consuming, and does not provide the most efficient means for electrically joining components.

In Casciotti et al, Conductive Gel Area Array Connector, U.S. Pat. No. 5,037,312 (Aug. 6, 1991) a gel is used to form a temporary electrical connection between components. The components are mechanically fastened together through aligned apertures, and are maintained in spaced alignment with rigid spacers. This construction requires extreme precision in locating the apertures of each component, and the insertion of fasteners into each aperture results in a difficult manufacturing process.

A conductive mesh is described in Rowlette, Sr., Ordered Area Array Connector, U.S. Pat. No. 5,163,837 (Nov. 17, 1992). Coatings of adhesive and contact elements are applied to the mesh, which is then cured. The conductive mesh is inserted between components which are driven together to form an electrical connection. This apparatus requires a complicated manufacturing process. Further, additional means must be supplied to urge the components together to form the electrical connection with the mesh.

Another prior art method for electrically bonding electronic devices is the IBM Dendrite Bond, which uses jagged metal particles with knife-like edges. This method provides only a one-time contact. Other prior art contacts include a solder coating, with or without flux, an indium low-temperature bond to provide a weak cold diffusion weld, and adhesive tape. Also, a shaped bump that concentrates force at its tip to pierce the component is known. Similarly, Nitto Denko uses a mushroom-shaped bump to focus the stress. A solder ball with a soft outer layer and hard inner core has also been used to concentrate stress. These prior art designs do not solve the problems of reducing the size and number of fragile components of the electronic devices, while increasing the devices' performance.

It is increasingly necessary that the number of fragile components of an electronic device, as well as the individual handling of such electronic devices, be reduced. It would therefore be a significant advance if such handling were eliminated or reduced as much as possible. It would be a further advance in the art to provide smaller, less fragile, and more efficient electronic devices.

### SUMMARY OF THE INVENTION

The invention provides a method and apparatus for manipulating electronic devices that minimizes individual device handling. The invention permits the reduction in size and number of fragile components of an electronic device during fabrication of single and multi-layer particle connect boards and further allows the testing, burn-in, and/or programming of multiple devices as grouped in carrying tubes, trays, or in die or wafer form.

A conductive layer is joined to a first planar side of a dielectric layer having two planar sides. At least one via is formed through said dielectric layer to said conductive layer to form a single-sided via. The conductive layer is maintained in aligned contact through the via with at least one device, such as an electronic device, a printed circuit board or an additional single-sided via.

A plurality of discrete electronic devices that are contained for transport in a carrier, such as a tube or a tray, are precisely positioned upside down for simultaneous probing at a test site that includes at least one channel defined by at least two spaced parallel dividers, and a plurality of spaced parallel ridges oriented perpendicular to the dividers. The devices are contacted by a probe array that is brought into aligned abutment with the upwardly projecting device leads.

### BRIEF DESCRIPTION OF THE DRAWINGS

FIG. 1 is a top plan schematic view of a preciser according to the invention.

FIG. 2 is a perspective, partially-sectioned, schematic view of a preciser according to the invention.

FIG. 3 is a partially cutaway, perspective, schematic view of a preciser according to the invention.

FIG. 4 is a perspective schematic view showing a preciser and a test array according to the invention.

FIG. 5 is a side elevation, sectioned, schematic view of a two-sided test array according to another embodiment of the invention.

FIG. 6a is a side elevation, sectioned, schematic view of a first contact according to the invention.

FIG. 6b is a side elevation, sectioned, schematic of a second contact according to the invention.

FIG. 7 is a schematic view of a third contact according to the invention.

FIG. 8a is a schematic plan view of a top trace of a ball-grid contact according to the invention.

FIG. 8b is a sectioned, schematic, bottom view of a bottom trace of the ball-grid contact according to the invention.

FIG. 8c is a schematic side view of the ball-grid contact according to the invention.

FIG. 8d is a partially sectioned schematic side view of a ball-grid contact according to the invention.

FIG. 9 is a side elevation, sectioned, schematic view of a heat exchanger having a device locator according to another, equally preferred embodiment of the invention.

FIG. 10 is a sectioned, schematic, side view of a single-layer single-sided via according to the invention.

FIG. 11 is a sectioned, schematic side view of a multi-layer single-sided via according to the invention.

FIG. 12 is a top view of the single-sided via according to the invention.

FIG. 13a is a top view of a contact array according to an alternative embodiment of the invention.

FIG. 13b is a perspective view of the contact array of FIG. 13a according to the invention.

FIG. 14 is a perspective view of an interposer contact according to another alternative embodiment of the invention.

FIG. 15 is a perspective view of another interposer contact according to another alternative embodiment of the invention.

### DETAILED DESCRIPTION OF THE INVENTION

One embodiment of the invention provides a method and apparatus for manipulating electronic devices that permits the reduction in size and number of fragile components of an electronic device during fabrication of single and multi-layer particle connect boards and further minimizes individual device handling, thereby allowing the testing, burn-in, and/or programming of multiple devices as grouped in carrying tubes, trays, or in die or wafer form.

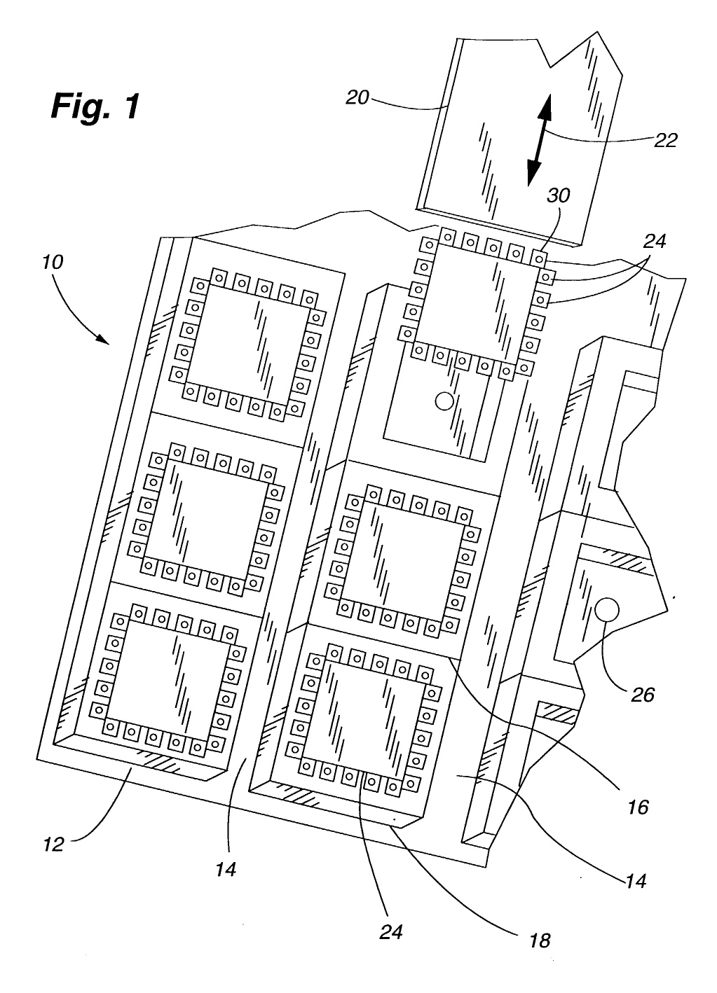

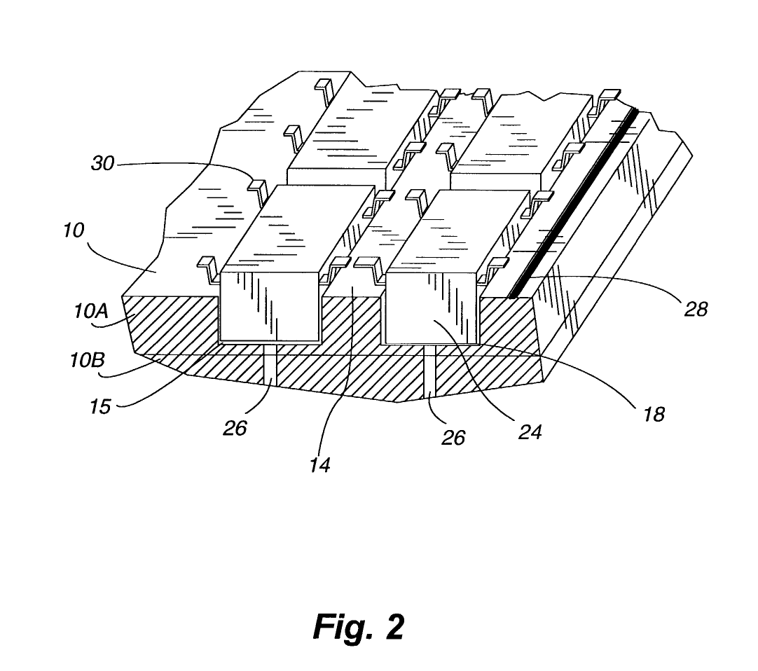

FIG. 1 is a top plan schematic view of a preciser according to a preferred embodiment of the invention. The preciser 10 includes at least two spaced, parallel dividers 14 that define a channel 15 (see FIG. 2). Spaced parallel ridges 16, preferably arranged normal to the dividers 14, partition the preciser into a test site array 12 having at least one individual recess 18 that is adapted to receive an electronic device, such as a packaged part 24.

The test site array provides a matrix in which the individual recesses are configured by positioning the dividers 14 and the parallel ridges 16 in a selected, spaced relation, one to the other. In this way, the recesses can be configured to receive different types of electronic devices, including but not limited to packaged devices, singulated semiconductor die and components, hybrids, multi-chip modules, and multiple component circuits.

In the preferred embodiment of the invention, the dividers and ridges project upwardly from a base portion of the preciser and are formed from such materials as, for example metal or plastic. The parallel ridges are preferably lower in height than the dividers, such that they provide a detent that demarcates a test site within a channel 15, but do not provide a substantial barrier to the free passage of devices within the channel, for example during loading or unloading.

Electronic devices are typically transported in various quantities in containers. The channel 15 allows electronic devices to be easily slid into position at the various recesses within the preciser from a container, such as a tube 20. To load the preciser with electronic devices, the tube containing the electronic devices is placed above the preciser 22, parallel to the channel, such that the parts may be slid from the container into the individual recesses by tilting the container. If desired, a bracket (not shown) may be located at the end of the channel to accept and orient the tube. Additionally, the recesses may be profiled to provide a receptacle that conforms to the shape of the part or component placed therein. For example, they may be generally circular in shape with a flat portion, such that the recess conforms to the shape of a wafer.

The container 20 opening is lowered toward the channel to discharge the electronic devices 24 therefrom by force of gravity. The container is then drawn along the channel to deposit the electronic devices in the various recesses along the channel. After the electronic devices are deposited into the channel, the preciser can be shaken, if necessary, to properly orient the electronic devices within the recesses. The ridges cooperate to help position the electronic devices within an appropriate recess. This procedure may be performed manually, although one skilled in the art would readily construct an apparatus for performing these tasks in an automated fashion.

The preciser may also include one or more vacuum ports 26 that provide a negative pressure to the electronic device to hold the electronic device securely within the recess. The vacuum port may be located within a recess or at any site on the preciser at which it contacts the electronic device, e.g. the side of a channel. The vacuum is provided and controlled by a vacuum system, as is well known in the art. Alternatively, a mechanical or chemical fastener may be used to secure the electronic devices within the recesses, or the invention may operate solely through the force of gravity.

After the test, burn-in, or program sequence is completed, the vacuum is released to free the electronic devices, which are slid back into the container, as shown in FIG. 1 by the arrow identified by the numeric designator 22.

More than one channel may be loaded with electronic devices at the same time. For example, the recesses in the preciser may match the orientation of electronic devices contained on a tray. To load the preciser, the preciser is placed over the tray and the tray and preciser are turned over together. The devices then fall into position within the preciser, and their placement is adjusted, if necessary, by shaking the preciser.

It should be appreciated that the preciser may be formed as an assembly that includes a base portion and a recess portion, such that the base and recess portion may be interchanged to accommodate device having different package sizes. For example, a single base 10b may be provided to which a number of different recess portions 10a may be attached as appropriate for the device in question. The base portion may contain redundant vacuum holes that match up to any specific device package accepted by a particular recess portion. Furthermore, the base assembly may comprise both an interposer and a preciser base portion, and may also include an integrated heat sink.

FIG. 2 is a perspective, partially sectioned schematic view of the preciser according to the invention. In the figure, a plurality of discrete electronic devices, such as the packaged parts 24, are precisely positioned upside down, i.e. in a dead bug position, in the preciser recesses 18. The term dead bug is used to describe the appearance of a packaged device when positioned upside-down, with its leads 30 pointing upwards. A live bug part is a part which is in an upright orientation. Dead bug orientation is significant in the invention because it allows the preciser to present an array of electronic devices having their leads oriented in such manner that they are readily contacted by a probe array for such operations as testing, burn-in, and/or programming.

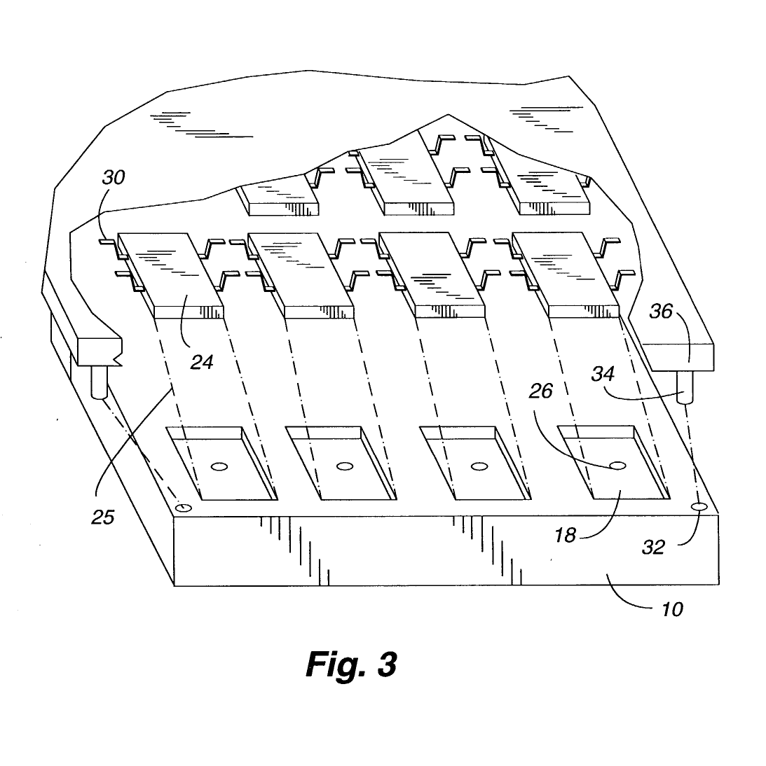

FIG. 3 is a perspective schematic view of a preciser that is adapted to receive a tray of electronic devices, all at the same time, according to the invention. The preciser is loaded with electronic devices as discussed above by setting the preciser over a tray of electronic devices and then turning the tray and preciser over together, such that the devices fall into complementary recesses within the preciser. The preciser includes at least one alignment hole 32. Once the preciser is loaded with electronic devices, a probe array 36 is brought into aligned abutment with the preciser and secured in that position by the mating of at least one alignment pin 34 on the probe array with an opposing alignment hole on the preciser. Alternatively, the pin may be placed on the preciser and the alignment hole formed in the probe array, or each of the probe array and preciser may include alignment pins and alignment holes. Additionally, mating grooves or other known alignment means may be used to assure proper registration of the probe array and the preciser.

The upwardly projecting leads of the electronic devices are contacted by an array of contacts formed on the probe array to perform a desired procedure. A seal 28 (FIG. 2), oriented parallel to the edge of the preciser, may be provided to maintain contact with a probe array during a test, burn-in, or programming sequence. The probe array is chosen as appropriate for its ability to perform various desired procedures on the electronic device. For example, the probe array may be a burn-in board, in which case a metal preciser may be provided to improve thermal transfer. The probe array may also be used to test or program electronic devices, such as EPROMs.

The electronic device 24 may be a plastic leaded chip carrier (PLCC) package. As the PLCC devices are slid dead bug fashion from a tube into the preciser 10, the spaced dividers 14 constrain the PLCC devices to fit within the recesses defined within the preciser channels. Once the packages are directed into the individual recesses, they are secured to the preciser by a vacuum at the vacuum port 26. The preciser may also be adapted for use with small outline integrated circuits (SOIC), super small outline integrated circuits (SSOIC), and thin small outline packages (TSOP). The preciser herein described is also readily adapted for testing a wafer or singulated die. For example, individual wafers may be aligned to the edge of the preciser for testing, or the recesses may be formed to receive singulated die during a test, burn-in, or programming sequence. In such applications, round recesses or alignment points are provided instead of, or in addition to, the matrix of parallel channels and ridges.

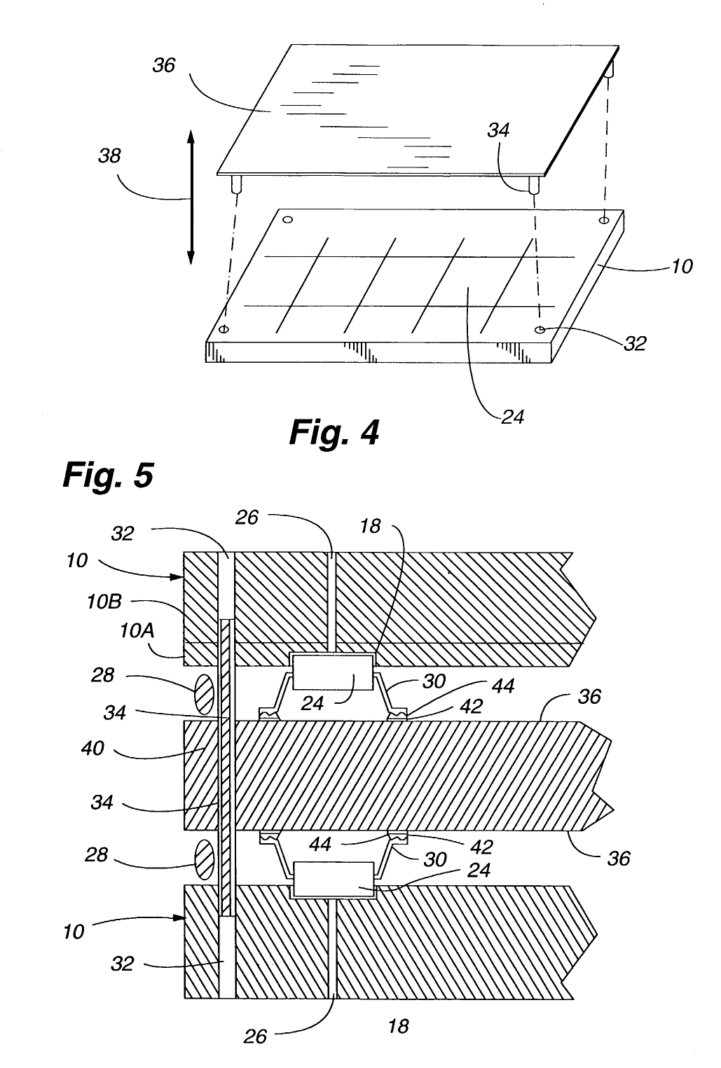

FIG. 4 shows a preciser 10 that is loaded with electronic devices 24. In the figure, placement of the probe array 36 relative to the preciser is shown by the arrow identified by numeric designator 38.

A multiple stack preciser is shown in FIG. 5. A two-sided test array shown in the figure includes a test board 40 having a probe array 36 provided on each side of the board. A pair of precisers 10, each containing one or more electronic devices, is arranged on opposite sides of the test board 40. One of the precisers includes a universal base portion 10b and a device specific channel portion 10a (discussed above).

A contact 44 is provided at each point on the probe array to which an electrical connection is to be established between the probe array and a corresponding electronic device. The contact is preferably formed of, or coated with, a particle enhanced material 42 formed of metal or metal coated hard-cored particles dispersed into a binder, such as is described in U.S. Pat. No. 5,083,697, issued Jan. 28, 1992, Particle Enhanced Joining of Metal Surfaces; U.S. Pat. No. 4,804,132, issued Feb. 14, 1989, Method For Cold Bonding; and U.S. Pat. No. 5,334,809, issued Aug. 2, 1993, Particle Enhanced Joining of Metal Surfaces. This material, also known as particle interconnect (PI), provides easily localized electrical, thermal, and/or mechanical communication across a temporary or permanent junction formed between opposing surfaces. Such material may be applied by such methods as thin film deposition. Alternate embodiments of the invention may use electroconductive elastomer, or solder to join the electronic device to the contact.

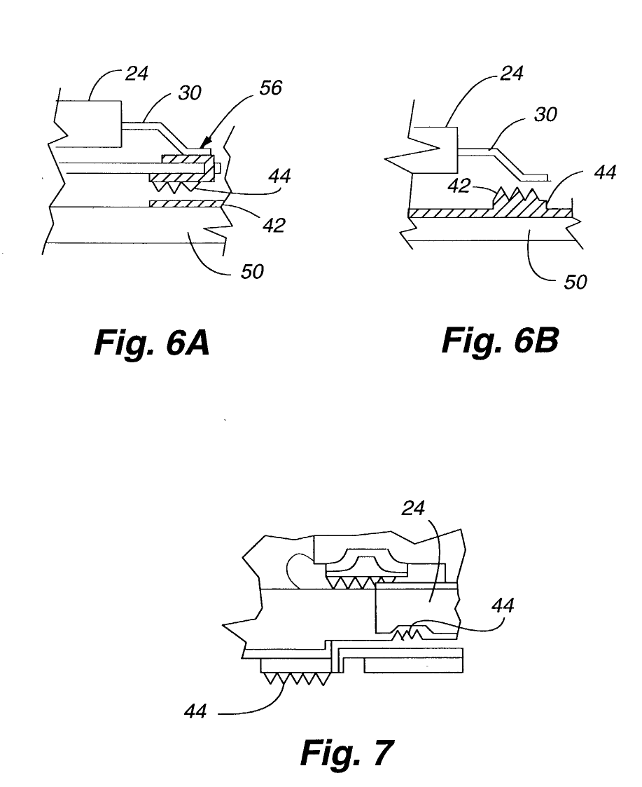

It is readily appreciated by one skilled in the art that alternate embodiments of the invention may require varying types and configurations of contacts adapted for use with different electronic devices. FIGS. 6a-6b illustrate different embodiments of contacts that provide an electrical connection between the electronic device and the probe array. These embodiments are suitable for retaining and testing single dies, but are also readily adaptable for use with multiple component or multiple layer electronic devices, and packaged devices.

FIG. 6a is a sectioned, side elevation schematic view of a first contact according to the invention. The lead 30 of an electronic device 24 is soldered to one side of a multi-chip module substrate 56 which has contacts 44 on its opposite side. A contact array 42 formed on a substrate 50 includes individual contacts that are formed of, or coated with, a particle interconnect material.

FIG. 6b is a sectioned, side elevation schematic view of a second contact according to the invention, in which the lead 30 is bonded directly to the contact 44 formed on the substrate 50 using a particle interconnect material.

A third contact is shown in FIG. 7, in which the 44 contacts alternate on opposite sides of an interposer 24. The invention finds application with an means for making an electrical connection by contacting two surfaces.

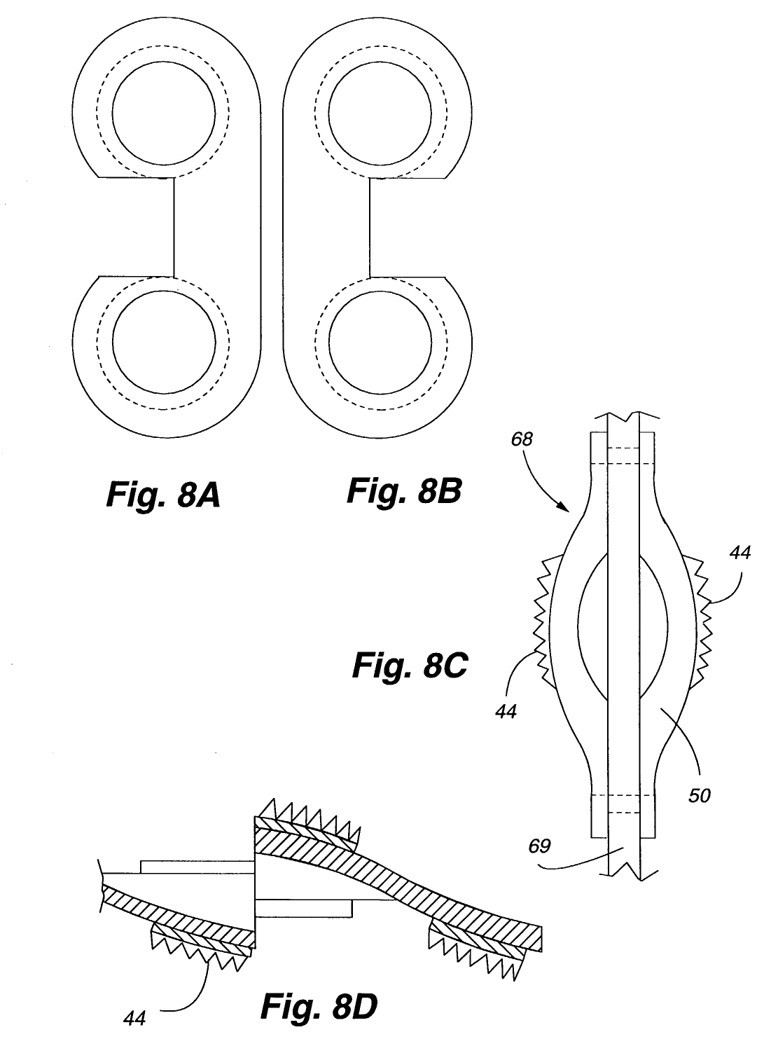

Enlarged schematic views of a ball-grid contact are shown in FIGS. 8a-8d in which FIG. 8a is a schematic plan view of an upper trace the ball-grid contact, FIG. 8b is a sectioned schematic bottom view of a lower trace of the ball-grid contact, FIG. 8c is a schematic side view of the ball-grid contact, and FIG. 8d is a partially sectioned schematic side view of a ball-grid contact. The ball grid array 68 includes contacts 44 on both sides of an interposer 69. The interposer can be deformed to form bumps that serve as contacts, or, alternately, the contacts can be formed by slitting the board or by punching in a pattern to cause puckering. One advantage of this type of contact is that it is able to accommodate bumps and other types of contact points that are of irregular or inconsistent height.

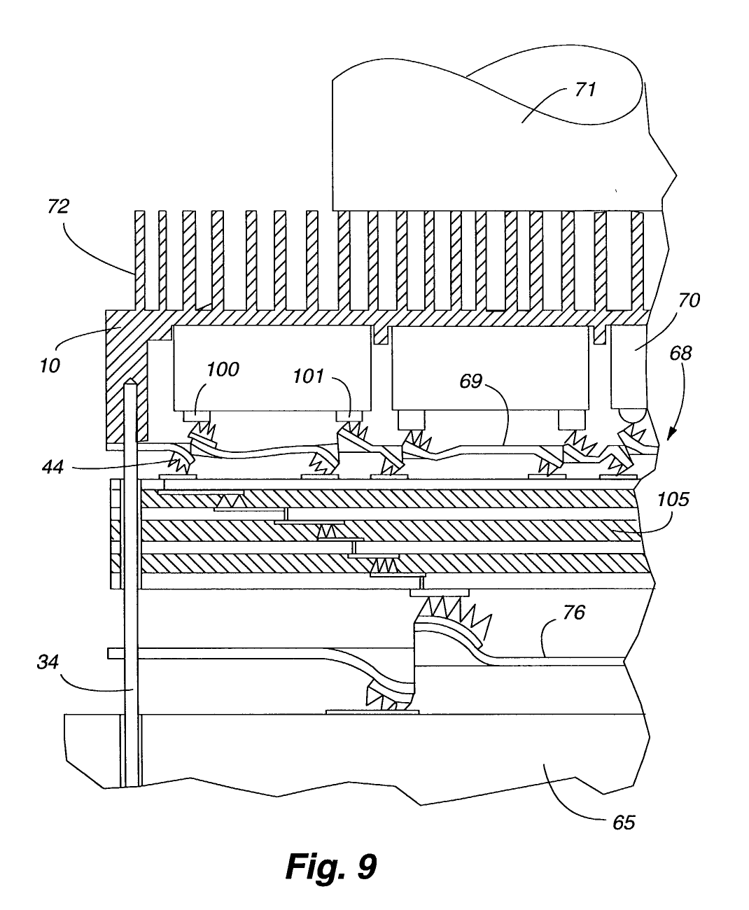

FIG. 9 is a sectioned, side elevation schematic of a heat exchanger having a device locator. In this embodiment of the invention, the preciser 10 is used to locate electronic devices precisely within a metal case 72. In one embodiment of the invention, the case provides a heat sink that may also include a fan 71. An electronic device 70 is held in place by the spring action between the device and a package interposer 76. A multi-layer particle enhanced array 105 is used to contact the device 70 via contacts 100, 101, 102 that may include, for example any or all of the embodiments previously discussed. For example, the device may have contacts with irregular heights, such as the contacts 100, 101 shown in the figure. In this case, a ball grid array 68 having contacts 44 (as described more fully in connection with FIGS. 8a-8d) is provided to accommodate height variations of the device contacts. Similar contact may be formed on the package interposer 76.

The interposer 65 is aligned with the heat exchanger and the preciser via an alignment pin 34. In other embodiments of the invention, different means of attachment, including but not limited to soldering or clamps may be used. It will be appreciated that different die pads, such as bumped or wire bond pads, may be used alone or in combination in alternate embodiments of the invention. The die is removable by unstacking the layers of the heat exchanger.

As technological advances have reduced the size of electronic devices, the difficulty of fabricating smaller and more complex components has been magnified. Additionally, it has become increasingly more difficult to locate or attach these components to precisely insure the proper functioning of the electronic device. An alternate embodiment of the invention reduces the steps required in the fabrication of electronic devices such as printed circuit boards, while also reducing the size of the device, and minimizing the failure of components, thus improving the performance of the preciser.

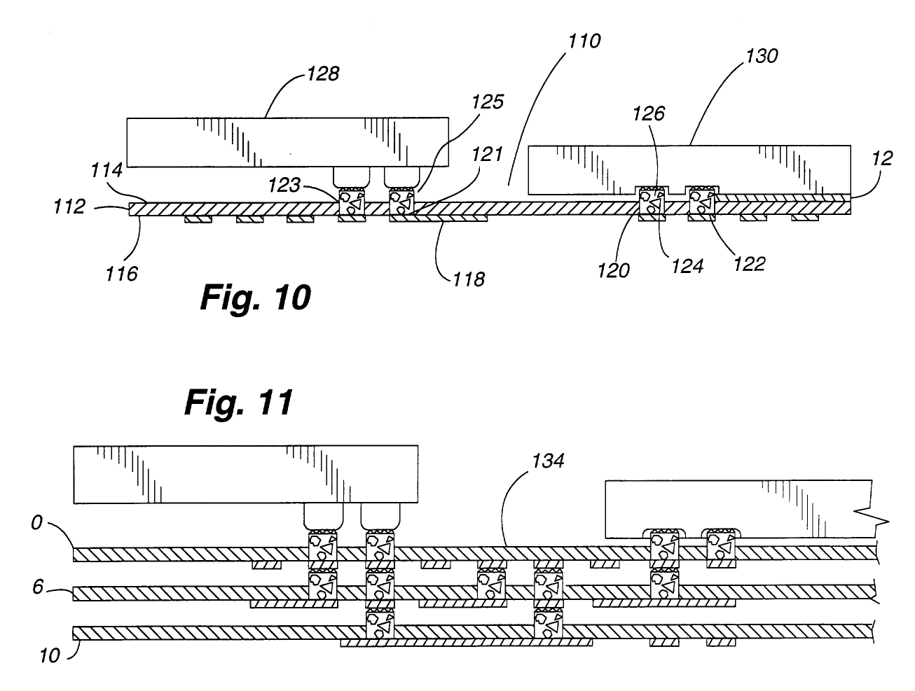

FIG. 10 shows a sectioned schematic side view of a single-layer single-sided contact board 110 according to the invention. The preferred embodiment of the invention is formed of a layer of dielectric material 112, having a first planar side 116 and a second planar side 114. The dielectric layer may include materials such as Kapton, ABS, PBC, polycarbonate, polyamide, FR4, polyester, or epoxy glass, and may also be adhesive. In a preferred embodiment of the invention, the dielectric material is Kapton film with a thickness of between 1 and 3 mm.

A first conductive layer 118 is joined to the second side of the dielectric layer. This conductive layer is preferably rolled copper foil. Alternate embodiments of the invention may use conductive layers of other materials. One continuous conductive layer may initially be joined to the dielectric material, and then patterned, perforated, or removed to expose portions of the second side of the dielectric layer. In another embodiment of the invention, a plurality of conductive layers may be joined to the second side to cover the desired areas. The laminated joining of the conductive layer according to the invention reduces prior art problems resulting from improper alignment of the conductor, as well as from contamination or degradation from exposure of the bond between dielectric and conductor.

At least one via 120 is formed through the dielectric material to expose the conductive layer 121. The vias may be formed prior to or subsequent to the joining of the dielectric and conductive layers. In a preferred embodiment of the invention, the vias are laser drilled, while other embodiments use mechanical drilling or punching to form the vias.

The exposed conductive layer may be joined, through the via, to at least one device, including but not limited to a bumped grid array (BGA) package 128, a land grid array (LGA) package 130, a bumped die (128), an unbumped flip chip (130), a printed circuit board, or an interposer thereby forming a multi-layer single-sided circuit interconnect. In the preferred embodiment of the invention, a particle enhanced material 122 formed of hard particles 124 dispersed into a binder 126, such as the particle interconnect material previously discussed, is used to join the conductive layers. The particle interconnect material is inserted or deposited into the via to contact the exposed conductive layer. The vias are preferably filled with particle interconnect material using an electroplating bath. Use of particle interconnect material permits the staggering of vias in multi-layer structures, unlike the prior art technology which uses mechanical fastening and thus requires precise alignment of the layers and vias. Further, Pi permits the staggering of the layered devices themselves. Accordingly, the invention provides a via that is more readily aligned, and that therefore requires less space on a substrate to accommodate misalignment.

In one embodiment of the invention, the particle interconnect material does not project beyond the second planar side of the dielectric layer 123. A device is layered over the second planar side, and heat and pressure are applied to compress the dielectric material and force the particle interconnect material to protrude from the via. A preferred embodiment uses an adhesive dielectric layer that bonds with the device to provide contact, and to form a sealed joint. This seal prevents the entry of oxidants and contaminants and holds the particle interconnect material in contact with the device, thus permitting electrical, thermal and/or mechanical communication with the device.

In another embodiment of the invention, the particle interconnect material projects beyond the second planar side of the dielectric layer 125. The particle interconnect material coating may then be selectively removed or patterned on the dielectric layer. Particle interconnect material containing an adhesive binder forms a bond between the conductive layer and the device. A temporary adhesive bond may be formed, permitting the removal, realignment, or replacement of the device. In the preferred embodiment, however, a permanent bond is formed. The particle interconnect material projection may additionally include dendrites or flux solder at its top. In yet another embodiment of the invention, an adhesive layer 127 is inserted between the dielectric material and the device, surrounding the protruding particle interconnect material bonds. The particle interconnect material may be inserted into the vias only, or, alternately, the dielectric material may be coated with particle interconnect material, filling the vias. Additionally, it will be appreciated that different die pads, such as bumped or wire bond pads, may be used alone or in combination with the particle interconnect material in alternate embodiments of the invention.

In the prior art, the via is lined with a conductive material, which projects from the dielectric material to form an annulus. Lack of precision in the alignment process requires the drilling of an enlarged annulus. Electrical contact is maintained when the device is brought into contract with the annulus. Imperfect alignment of the device and annulus results in reduced electrical conductivity and circuit density. Particle interconnect material, however, does not require as precise an alignment as the annulus of the prior art and the annulus size may be reduced. The fabrication process is simplified, because all of the steps of the prior art are performed in one operation. The invention therefore provides more efficient performance with a less complicated process, a smaller space factor, and at a lower cost.

While a multilayer circuit board produced in accordance with the prior art requires a large aspect ratio (i.e. the ratio of the width of the via's annulus to the depth of the via's hole) because of misalignment between layers in the circuit board and the need to plate through the via to interconnect the various layers, the invention avoids such problems because each layer of the circuit is composed of a thin (e.g, about 2 mil) dielectric that readily interconnects with a device or next circuit layer, thereby completing interconnection within the via at each level as the level is formed by punching through the dielectric layer to make contact with the next adjacent layer. Additionally, forming large holes for prior art vias requires that a large hole via drilled to meet the aspect ratio requirements, yet such techniques are still subject to such problems as barrel cracking and layer separation. It has been found that the invention allows a typical reduction of the via aspect ratio from about 10-20:1 to about 1-2: 1.

In this embodiment of the invention, a connection across each via may be formed, for example, by use of any of the following techniques:

Hard coated particles may be packed into the via. The particles are composed of a material selected from the group consisting of silver, copper, titanium, gold, aluminum, platinum, nickel, tin, magnesium, lead, indium, steel or metal hard coated particles, and conductive hard particles, including silicon carbide, and mixtures and alloys thereof; and are preferably solid particles having an average size of about 6-200 μm, or flakes having an average size of 20-200 μm. Such particles are further described in L. DiFrancesco, Method For Cold Bonding, U.S. Pat. No. 4,804,132 (Feb. 14, 1989); and L. DiFrancesco, Particle-Enhanced Joining of Metal Surfaces, U.S. Pat. No. 5,083,697 (Jan. 28, 1992), which are incorporated herein by reference. Each particle may include a hard core, made of diamond or silicon carbide, and a metal coating, made of nickel. In those instances where increased electrical or thermal conductivity is required, the particles should preferably consist of silver, copper, titanium, gold, aluminum, or platinum, or a combination or alloy of the above. Alternately, a carbon filled particle may be used. When insulating properties are required, a non-conductive core, such as alumina, quartz, or borosilicate may be used. In an alternate embodiment, the binder material itself may provide electrical, thermal, or mechanical properties, for example the binder may be an anisotropic, electrically conductive adhesive.

Hard coated particles may be placed in an adhesive carrier, such as Hysol 4510, Ablestick 967-1, Eastman 910, Loctite Stud Lock, and Norland 60 and 61 that can be cured to form a permanent bond after the material is applied to the surface of a substrate. The adhesive is preferably cured using a one or two-part process, for example a two-part 5-minute setting epoxy or a two-part underwater curing epoxy. Anaerobic curing conditions may be used to improve the electrical conductivity of the bond by preventing oxidation of the hard particles included in the material, for example by using Eastman 910 or Loctite Stud Lock. A thermoplastic gel binder, such as Elform thermoplastic adhesive may be used for those materials that tolerate variances in temperature, and a pressure sensitive binder gel, such as ultrahigh strength 3M pressure sensitive tape or 3M Post-It® low strength, pressure sensitive transfer tape may also be used to join components. In another embodiment of the invention, an adhesive may be applied to a sensitive substrate that cannot tolerate application of heat or pressure. Organically-based binder gel, such as airplane glue, is applied to the substrate. The adhesive is then cured by ablation, dissolution, or volatilization of the organic carrier, leaving the substrates bonded by the cured adhesive. Another embodiment of the invention provides an adhesive having a binder that may be cured by ultraviolet radiation, such as Norland 60 and 61. Ultraviolet curing is fast and it does not require the use of solvents that may otherwise damage sensitive substrate surfaces. The ability of this material to be used in either its uncured state, or after it is cured by a method specific to the particular needs of the application, makes the adhesive especially well suited for the automated surface-mounting of integrated circuits, as well as in the fabrication of microelectromechanical systems.

Hard coated particles may be placed into the via and then heated to sinter or melt the particle coating to thereby join the particles together mechanically and electrically.

A thermal curing adhesive may be used, where the adhesive shrinks as it cures and thus draws the particles together into a tightly bound matrix. Such cure may occur at room temperature or when the adhesive is heated, such that the adhesive matrix cures with a residual internal stress. Such stress may be enhanced by curing the adhesive under pressure. In this way, the invention may take advantage of the typically undesirable trait of some adhesives to exhibit a large thermal coefficient of expansion.

The vias may be filled with a thermally and/or electrically conductive material, such as solder, metallic powder, and the material may be sintered or flowed to complete the pathway through the via.

The vias may be filled with an organometallic ink.

The vias may be electroplated by any known plating technique.

The dielectric layer may be made of such materials as ABS, polyester, and polyimide, having the properties that the layer shrinks when heated to apply compressive pressure to the inner surfaces of the via and thereby force particles within the via into intimate electrical and mechanical contact.

Hard diamond particles may be used in a conductive matrix for applications requiring a ceramic substrate. Such materials as alumina, aluminum oxide, aluminum nitride, and beryllium may also be used.

A insulating material, such as fusing glass, may be used in the conductive matrix.

FIG. 11 shows a sectioned schematic side view of another embodiment of the invention, the multi-layer single-sided interposer. In this embodiment, multiple layers of single-sided interposer 110 are joined to form a multi-layer printed circuit board 134. In the preferred embodiment, a layer of Bond-Ply or similar material 136 is sandwiched between, and joined to, two layers of single-sided interposers. These layers may be formed according to the embodiments previously described for the single-layer single-sided interposer. In alternate embodiments of the multi-layer single-sided interposer, a plurality of layers of single-sided interposers and devices may be joined.

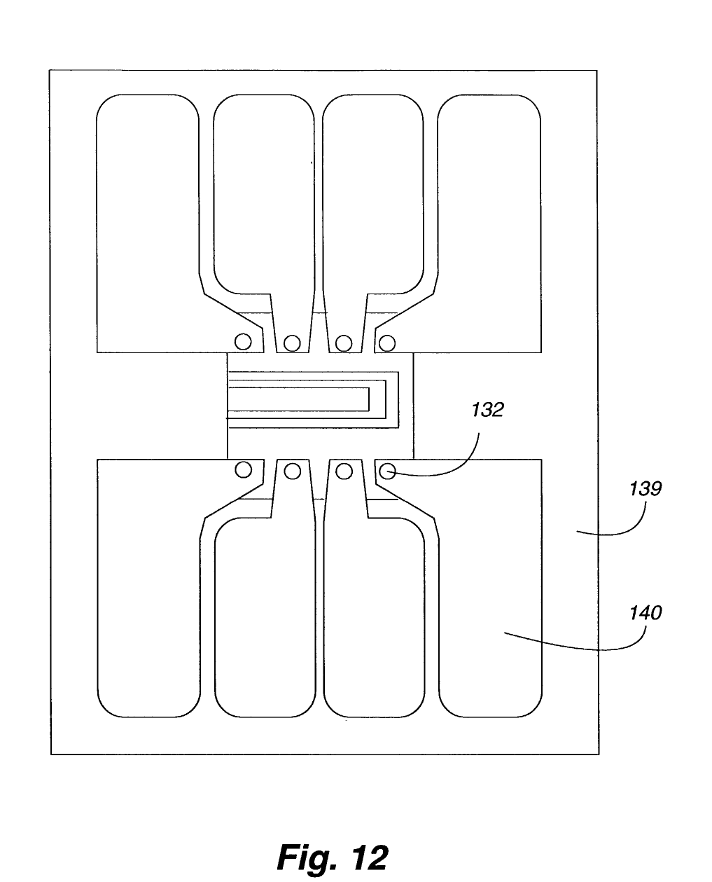

FIG. 12 is a top view of the single-sided interposer according to an embodiment of the invention that may be used, for example, in smart card application. In this embodiment of the invention, a plurality of traces 140 are formed on the surface of a substrate 139 to provide contacts for the smart card. The card is made of a laminate material, such as ABS, 5-10 mils thick having dimensions of 0.43×0.47 inches, although a substrate having other sizes is within the scope of the invention.

Vias are punched into the bare material at die pad attachment points 132. Copper foil is laminated to the front side of the ABS board after the vias are punched, for example the ABS material may comprise a thermoplastic adhesive system. Particle interconnect material vias are built up flush to the backside of the ABS surface, i.e. no photoresist image is used. Front pads and traces are formed of nickel/gold, the board is copper etched, and if multiple boards have been formed, the boards are singulated. The die is heated and pressed against the ABS material until the die pad is attached to the particle interconnect material bumps formed on the surface. In this step, the die sinks into the ABS material until the recessed die pads are supported against the particle interconnect material bumps. This embodiment of the invention is also useful as a lead frame and die package.

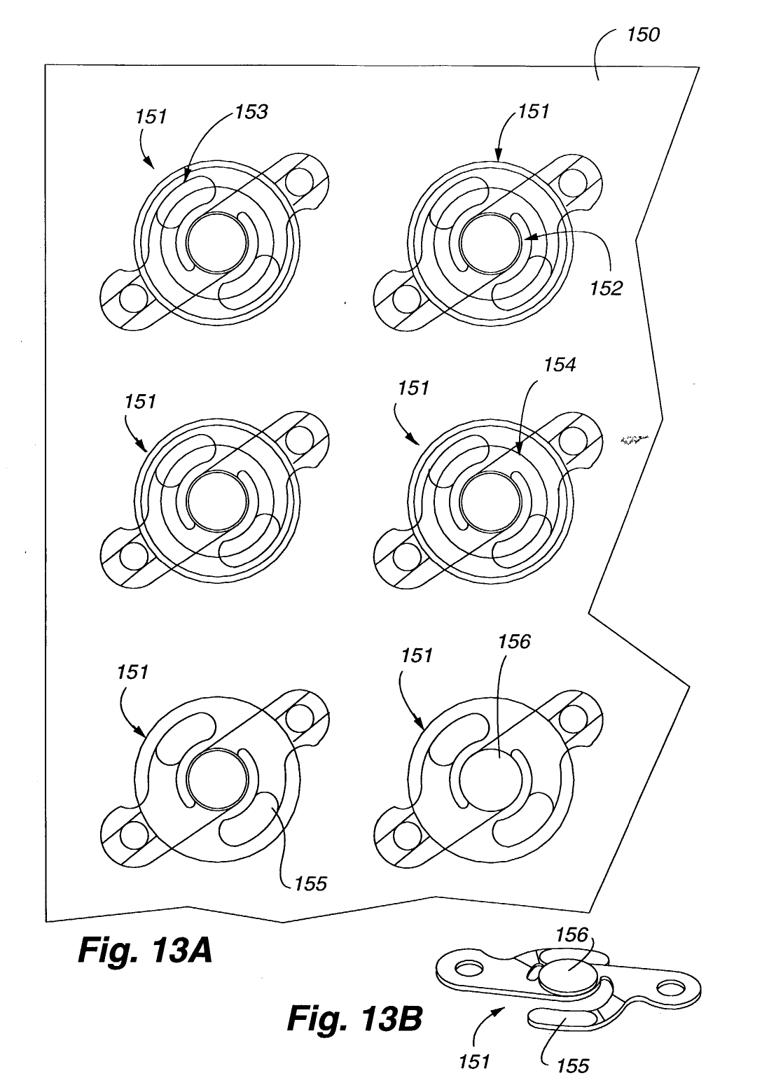

FIG. 13a is a top view of a contact array according to an alternative embodiment of the invention. In the figure, a substrate 150 includes a plurality of two-sided contacts151, each of which includes a first contact 156 that projects from the plane of the substrate in a first direction, and a second contact 155 that projects from the plane of the substrate in an opposite direction, such that an interposer is provided that is capable of interfacing a plurality of devices and/or contact arrays. Each contact includes a particle interconnect material formed on its surface. The first contact 156 is generally circular in shape and is formed to project from a center of a punched out area 153 on a bridged portion of a conductive material 152. The second contact 155 is defined by the punched out area 153 and may consists of two or more wing portions 154.

FIG. 13b is a perspective view of the contact array of FIG. 13a according to the invention. As shown in the figure, the contact provides a spiral, radial beam structure. The substrate itself may be formed of a metal or other conductive material, such as a beryllium copper sheet. Because the contact herein described is provided with an opposing, projecting set of contact wings, this embodiment of the invention is particularly useful for such applications as a die interposer or as a keyboard switch, where a button array is placed above a contact array, and an interconnect array is formed below the contact array. The contact wings typically project about 10-20 mil or less above and/or below the plane of the substrate.

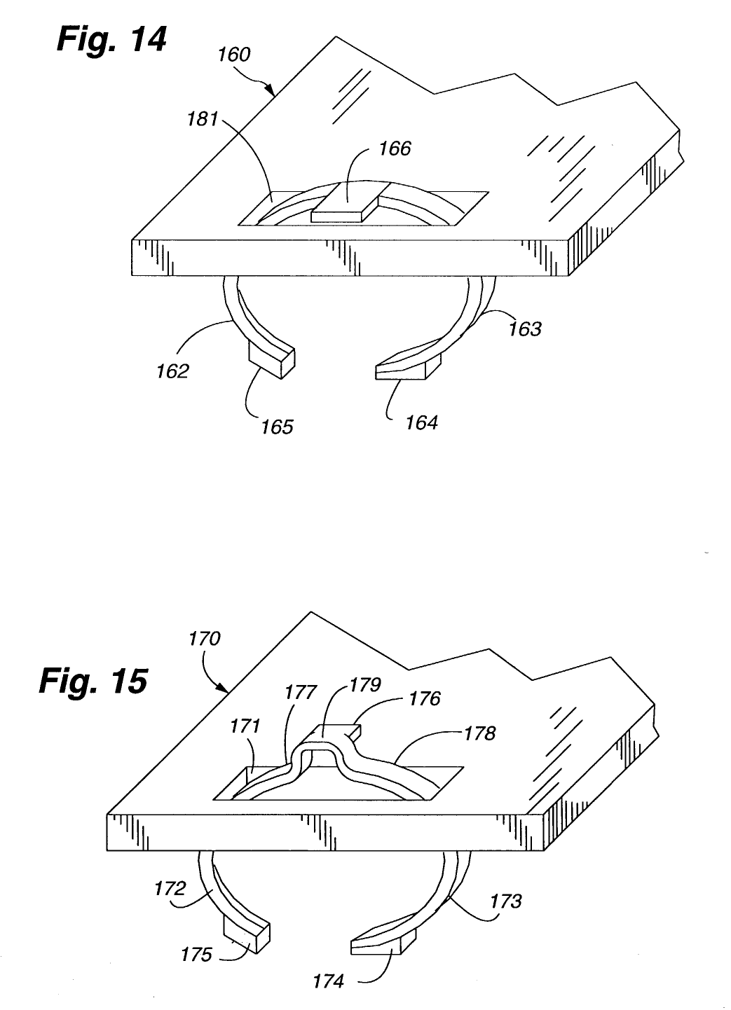

FIG. 14 is a perspective view of an interposer contact according to another alternative embodiment of the invention. In the figure, a substrate 160 includes one or more contacts, each of which includes a first contact segment 166, which may be formed of, or coated with, a particle interconnect material, and which includes one or more second contact segments 162, 163, which are formed by cutting or punching out contact wings 161, and by bending such wings to project downwardly from the plane of the substrate. The second contact segments may include a coating of particle interconnect material 164, 165. This embodiment of the invention provides a single sided board having an equivalent via formed without drilling to provide an electrical contact on both side of the board.

FIG. 15 is a perspective view of another interposer contact according to another alternative embodiment of the invention. In the figure, a substrate 170 includes one or more contacts, each of which includes a first contact segment 176, which may be formed of, or coated with, a particle interconnect material, and which includes one or more second contact segments 172, 173, which are formed by cutting or punching out contact wings 171, and by bending such wings to project downwardly from the plane of the substrate. The second contact segments may include a coating of particle interconnect material 174, 175. This embodiment of the invention provides a single sided board having an equivalent via formed without drilling to provide an electrical contact on both side of the board. As shown in the figure, the first contact segment includes an upwardly projecting contact segment 179, providing an upwardly and downwardly projecting set of complementary contacts that are secured to the substrate 170 at two attachment points 177, 178.

Although the invention is described herein with reference to the preferred embodiment, one skilled in the art will readily appreciate that other applications may be substituted for those set forth herein without departing from the spirit and scope of the present invention. For example, the particle interconnect material may be used in conjunction with metallurgical bonding formed by rubbing or sliding metal parts together to break down the metal oxides. The conductive layer and device may be joined by a large particle, as well as by particle enhanced material. The particle interconnect material may be applied as a matrix containing binder and particles, or the binder and particles may be applied separately. Accordingly, the invention should only be limited by the Claims included below.

1. An electrical contact comprising:
a substrate;
a first contact segment projecting in a first direction from a substrate plane; and
at least one second contact segment formed in a radial spiral relative to said first contact segment and projecting in a second direction from said substrate which is opposite that of said first contact.

2. An electrical contact comprising:
a central contact segment projecting in a first direction from a substrate plane; and
at least one contact wing contiguous with, and bent to project in a second direction from said substrate which is opposite that of said central contact.

3. The electrical contact of claim 2, further comprising:
a particle enhanced material formed on at least one of said central contact and said contact wing.

4. The electrical contact of claim 2, further comprising:
a spring segment formed on either side of said central contact, wherein said first contact is supported for biased projection in said first direction from said substrate plane.

5. An electrical contact comprising:
an electrically conductive material plate defining a central planar contact base;
a plurality of integral mounting tabs coplanar with and extending from said base; and
a plurality of contact leaves integral with and extending spirally from said base, said leaves being mechanically deformed from the plane of said base to form independent spring leaf contacts.

6. An electrical contact comprising:
an electrically conductive material plate defining a central planar contact base;
a plurality of integral mounting tabs coplanar with and extending from said base;
a plurality of contact leaves integral with and extending spirally from said base, said leaves being mechanically deformed from the plane of said base to form independent spring leaf contacts; and
a particle-containing metal plating on said contact base.

7. An electrical contact comprising:
an electrically conductive material plate defining a central planar contact base;
a plurality of integral mounting tabs coplanar with and extending from said base;
a plurality of contact leaves integral with and extending spirally from said base, said leaves being mechanically deformed from the plane of said base to form independent spring leaf contacts;
a particle-containing metal plating on said contact base; and
a particle containing metal plating on each of said leaves.

8. The electrical contact as defined in claim 5 further comprising two leaves.

9. The electrical contact as defined in claim 6 further comprising two leaves.

10. The electrical contact as defined in claim 7 further comprising two leaves.

11. An electrical contact comprising:
a planar central contact segment projecting in a first direction from the plane thereof;
a contact leaf contiguous with and bent to project in a second direction from said plane which is opposite that of said central contact; and
a particle enhanced material on at least one of said central contact and said contact leaf.

12. The electrical contact as defined in claim 11 further comprising at least one additional contact leaf contiguous with and bent to project in said second direction from said plane.

13. The electrical contact as defined in claim 12 further comprising a particle enhanced material on said central contact and on each additional contact leaf.

14. An electrical contact comprising:
an electrically conductive material plate defining a central planar contact base;
a contact leaf integral with and extending spirally from said base;
a plurality of integral mounting tabs coplanar with and extending radially from said base; and
a particle enhanced material on at least one of said central contact and said contact leaf.
